(19) United States
(12) Patent Application Publication
(10) Pub. No.: US 2026/0150221 A1
(43) Pub. Date: May 28, 2026

(54) DISTRIBUTED SMALL-SCALE REACTOR POWER SYSTEM FOR DATACENTERS

(71) Applicant: Microsoft Technology Licensing, LLC, REDMOND, WA (US)

(72) Inventors: Ehsan NASR AZADANI, Sammamish, WA (US); Sean Michael JAMES, Olympia, WA (US); Phillip Todd NOE, Hixson, TN (US)

(21) Appl. No.: 18/962,904

(22) Filed: Nov. 27, 2024

(51) Int. Cl. H05K 7/14; H02J 9/06

(52) U.S. Cl. CPC H05K 7/1492; H02J 9/061

(57) ABSTRACT

A distributed small-scale reactor power system includes: a first set of small-scale reactors configured to supply power to a datacenter that includes a plurality of IT racks. The system also includes a set of power converters, where each small-scale reactor is operatively coupled to at least one power converter. Each power converter is also operatively coupled to at least one IT rack. In some aspects, the set of small-scale reactors is configured in a ring topology to provide power sharing and redundancy.

### BACKGROUND

Datacenters contain IT (‘Information Technology’) infrastructure, often housed in racks, that includes compute, storage, networking, and other devices. Need for compute, storage, and associated networking devices is increasing rapidly as applications such as artificial intelligence and cloud computing increasingly utilize such resources. As such, the number of datacenters is increasing and the density of IT infrastructure within datacenters is increasing. With increased density of IT infrastructure within a datacenter, power demand of each datacenter is also increasing.

Scaling density within a particular datacenter and scaling the total number of datacenters is currently prohibitive due to existing power systems. As power demand of each individual data center increases and the number of datacenters also increases, the electrical grid could face challenges to meet the increased electricity demand of datacenters with required availability. Construction of a conventional grid power plant to supply additional power requires a massive amount of capital, a long lead time, regulatory hurdles, and environmental concerns. Additionally, such conventional grid power plants normally have a very large power capacity. Constructing such a new power plant based on a smaller scale out (such as increased density of a single datacenter or two), may be viewed as inefficient in the short term even if the long-term needs for the total power capacity of the plant will exist.

### SUMMARY

According to embodiments of the present disclosure, various distributed small-scale reactor power systems are disclosed along with apparatus for managing availability of power in a datacenter and methods for supply power utilizing a small-scale reactor power system.

In some aspects, the distributed small-scale reactor power system includes a first set of small-scale reactors configured to supply power to a datacenter. The datacenter includes a plurality of IT racks. The small-scale reactor power system also includes a set of power converters. Each of the small-scale reactors is operatively coupled to at least one power converter. Additionally, each power converter is operatively coupled to at least one IT rack.

In some aspects, the small-scale reactors are configured in a ring topology to provide redundant AC (‘Alternating Current’) power to the power converters. Each of the power converters is configured to receive AC power from two or more of the small-scale reactors and provide DC (‘Direct Current’) power to one or more of the IT racks.

In some aspects, a plurality of datacenters may each be coupled to different set of small-scale reactors. That is, for a plurality of datacenters, there may be a plurality of sets of small-scall reactors, one set for each of the datacenters. In such an aspect, the plurality of sets of small-scall reactors may configured in a ring topology to provide redundant power to the datacenters.

### BRIEF DESCRIPTION OF DRAWINGS

FIG. 1 illustrates a block diagram of an example distributed small-scale reactor power system in accordance with some embodiments.

FIG. 2 illustrates a block diagram of an example datacenter that includes a distributed small-scale reactor power system in accordance with some embodiments.

FIG. 3 illustrates a block diagram of an example datacenter that includes a distributed small-scale reactor power system that is coupled to an electrical grid in accordance with some embodiments.

FIG. 4 sets forth a line diagram of a power system in accordance with some embodiments in which a set of small-scale reactors is coupled to a Medium voltage AC power supply.

FIG. 5 sets forth a line diagram of a power system in accordance with some embodiments in which a set of small-scale reactors is coupled to a Low voltage AC power supply.

FIG. 6 sets forth a line diagram of a power system in accordance with some embodiments in which each small-scale reactor of a set is coupled to a different row of IT racks.

FIG. 7 sets forth a flow chart illustrating an example method for managing availability of a distributed small-scale reactor power system in accordance with some embodiments.

FIG. 8 sets forth a flow chart illustrating another example method for managing availability of a distributed small-scale reactor power system in which load is used to determine power output in accordance with some embodiments.

FIG. 9 sets forth a flow chart illustrating a method of providing power by a distributed small-scale reactor power system in accordance with some embodiments.

FIG. 10 sets forth a flow chart illustrating another method of providing power by a distributed small-scale reactor power system in accordance with some embodiments.

FIG. 11 sets forth a block diagram of an example computing device configured to manage availability of a distributed small-scale reactor power system in accordance with some embodiments of the present disclosure.

### DESCRIPTION OF EMBODIMENTS

Building conventional power generation systems that include large power plants providing power through a vast electrical grid is time consuming and requires development of an entire power chain from power plants to transmission lines. Conventional electrical grids also lack the reliability needed to provide high availability for such high-density IT loads at large scale. Examples of high-power demand IT loads may include AI related applications, cloud services, and the like executing on advanced graphics processing units, compute servers, storage systems, high bandwidth networking devices, and the like. As demand for such loads increases, the demand for additional IT infrastructure in datacenters and the demand for additional datacenters also increases. As such, power demand by individual datacenters and datacenters as a group is increasing and is expected to continue increasing in the foreseeable future.

To provide the required scaling, increased power demand, reliability (and thus, high availability of IT infrastructure and IT workloads), a distributed small-scale reactor power system is described herein. A small-scale reactor, as the term is used here, refers to any reactor that can be constructed more quickly than a conventional grid power plant, can be installed at a location relatively near or within a datacenter or a colocation facility, requires less capital investment to construct and install than a conventional grid power plant, is generally constructed in a modular fashion, and has a physical footprint and capacity less than that of a typical grid power plant. With less capacity, the number of reactors needed for powering a single datacenter can be tailored based on expected power demand of that datacenter, thus reducing wasted power generation.

Examples of a small-scale reactor include a microreactor or a nanoreactor. A microreactor is a small nuclear reactor that can operate as part of the electric grid, independently from the electric grid, or as part of a microgrid. Some microreactors generate up to 20 megawatts of thermal energy that can be used to generate electricity, up to approximately 10 megawatts electric for example, and can provide heat for industrial applications. Microreactors are designed to be portable and can be hauled by a semitractor-trailer. Microreactors are generally 100 to 1,000 times smaller than conventional nuclear reactors. A nanoreactor is similar to that of a microreactor, but generally has a lower capacity output and a smaller physical footprint. For ease of explanation, except when otherwise specified, the term ‘reactor’ is used here to broadly encompass a system that includes a reactor, a generator that generates power based on thermal output of the reactor, and any other devices or materials utilized in the generation of electrical power.

The example small-scale reactor power systems described herein are also referred to as ‘distributed’ in that each datacenter is powered by a set of small-scale reactors. Each set of reactors for a datacenter may be configured for power sharing so that no one reactor is required to provide all power for the entire datacenter. Additionally, a set of reactors may be ‘distributed’ in that the set may be configured for redundancy so that loss of power from any one reactor does not affect overall availability of the datacenter. Further, small-scale reactor power systems of multiple datacenters (or multiple colocation facilities) may be coupled together for distributed power usage and redundancy between datacenters or colocation sites. That is, a first datacenter may be configured to receive power from at least one reactor that is not included in the set of reactors local to the datacenter. In this way, capacity lost when a small-scale reactor local to the first datacenter is offline may be replaced, in some examples, by capacity of one or more small-scale reactors located at a second datacenter.

Small-scale reactor power systems as described herein can be configured to operate independently from the electrical grid or in a manner in which the electrical grid is utilized only as a redundant system on-demand. Additionally, a small-scale reactor power system as described here may be configured for grid forming, grid following, or both. Grid forming refers to the process by which a power generation source actively establishes and controls the voltage, frequency, and overall stability of a microgrid and is not connected to a utility-based electrical grid. Unlike traditional grid-following generators, which synchronize with the existing grid conditions, grid-forming generators create a reference for the microgrid's operation, essentially “leading” the microgrid and establishing key parameters that other systems follow.

Grid following refers to a method used by power generation sources to synchronize their output with the existing grid. Instead of actively controlling grid voltage or frequency, grid-following devices rely on the grid's established parameters and adjust their output accordingly. These systems follow the grid's voltage and frequency signals. In the case of the small-scale reactor systems described here, the grid following operations may be utilized as part of a ‘black start’ process in which one or more of the set of reactors at a particular datacenter may be started up by synchronizing with the frequency and voltage of the grid after an outage or at the initial start-up of a reactor.

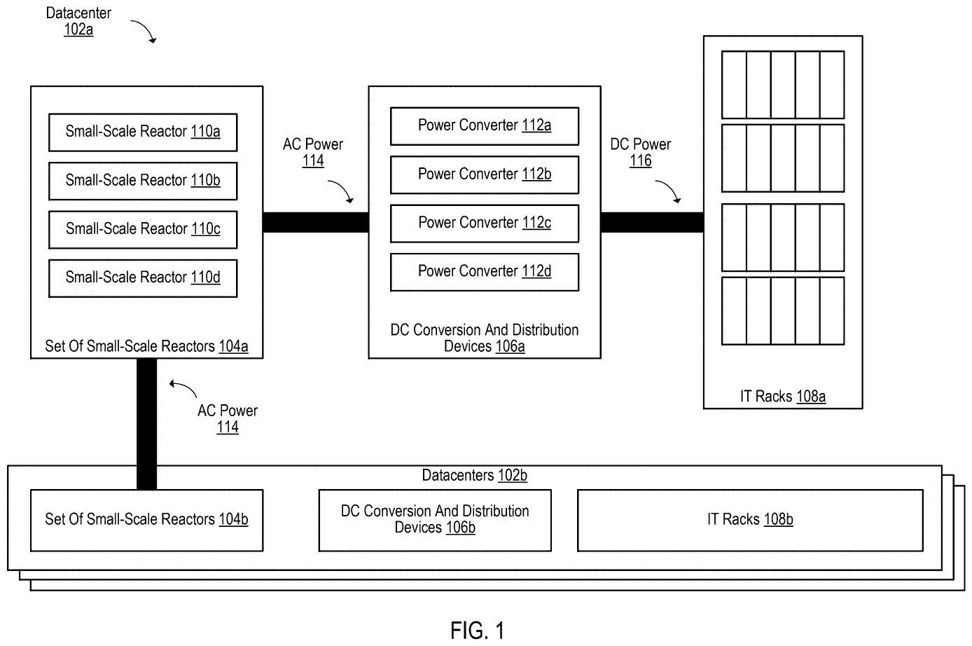

For further explanation, FIG. 1 illustrates a block diagram of an example distributed small-scale reactor power system in accordance with some embodiments. The example system of FIG. 1 includes a number of datacenters 102 a and 102 b. A first datacenter 102 a in the example of FIG. 1 includes the example datacenter 102a of FIG. 1 includes a set 104a of small-scale reactors, DC conversion and distribution devices 106a, and a number of IT racks 108a.

IT racks in a datacenter are utilized to organize and house various IT devices including, for example, CPU-based servers, GPU-based servers, networking switches and routers, uninterruptable power supplies, storage devices, and so on. Racks, typically made from sturdy metal, are often tall, vertical enclosures. Such racks may be built to a standardized width, such as 19 inches, to accommodate different types of equipment in a uniform way. Each rack is divided into units, commonly called a ‘U,’ where 1U is 1.75 inches in height, allowing for precise configuration based on the height of the devices (number of U's) being installed. Some IT racks may be high-bay racks. A high-bay rack may be double (or greater) the height of other conventional IT racks. Such high-bay racks increase the density of power demand by enabling a greater number of power consuming devices to be installed in the same footprint as a conventional IT rack.

The IT racks 108a of FIG. 1 receive DC power 116 from power converters 112a, 112b, 112c, and 112d included in a set of DC conversion and distributions devices 106a. In some embodiments, the IT racks 108a may receive AC power instead of DC power from the power converters. In such an embodiment, the IT racks 108a may include various DC conversion and distribution devices 106a. DC distribution devices may include breakers, busbars, PDUs (‘Power Distribution Units’), and the like. A power converter is a device that is configured to convert AC power to AC power at a different level or phase, AC power to DC power, DC power to AC power, DC power to DC power at a different level. Combinations of different types of converters can operate as a single power converter. For example, a transformer can be coupled to a rectifier in which the transformer operates as an AC-AC converter (stepping-up or stepping-down the AC power) and the rectifier converts the AC power output from the transformer to DC power. Another example of a power converter is a solid-state transformer.

A solid-state transformer (SST), power electronic transformer (PET), or electronic power transformer is an AC-to-AC converter, a type of electric power converter that replaces a conventional transformer used in electric power distribution. An SST is a collection of high-powered semiconductor components, conventional high-frequency transformers, and control circuitry which is used to provide a high level of flexible control to power distribution networks. An SST can step-up or step-down AC voltage levels like conventional transformers but offers several advantages. For example, an SST may enable bidirectional power flow, input or output either AC or DC power, actively and dynamically change power characteristics such as voltage and frequency levels, improve power quality relative to conventional transformers (via reactive power compensation and harmonic filtering, for example,), and greatly reduce the physical size and weight of individual transformer packages with equivalent power ratings.

In the example of FIG. 1, the power converters receive AC power 114 from the set 104a of small-scale reactors 110a, 110b, 110c, 110d and convert the AC power 114 to DC power 116 for distribution to the IT racks 108a. Readers will recognize that power converters useful in a distributed small-scale reactor power system according to embodiment of the present disclosure, may be implemented in a variety of manners and with a variety of devices. In some examples, such power converters may be AC-to-AC step-down converters that convert Medium voltage AC to Low voltage AC and distributes the Low voltage AC to the IT racks of a data center. The IT racks, in such an example, may include AC-to-DC converters. In some examples the power converters shown in the example of FIG. 1 may be implemented at the rack or row level and receive AC power from the small-scale reactors and convert the AC power to DC power at the rack or row level without other intervening converters. Other example implementations are described below in further detail.

In the example of FIG. 1, the set 104a of small-scale reactors 110a, 110b, 110c, 110d may be configured for redundancy and power sharing. For example, each of the small-scale reactors may be operatively coupled to provide AC power to more than one power converter. The term ‘operatively coupled’ here encompasses any mechanical and electrical connections and devices that may be utilized to couple a small-scale reactor to a power converter. Such connections and devices may include conductor lines, bus bars, circuit breakers, and so on. Power sharing and redundancy may be provided by configuring the small-scale reactors in a ring topology as described below in further detail.

In addition to the datacenter 102a, the set 104a of small-scale reactors may also be coupled to sets 104b of small-scale reactors of one or more other datacenters 102b. Such a set 104b of small-scale reactors of datacenter 102b may be coupled in a similar manner to those of datacenter 102a: to DC conversion and distribution devices 106b and to IT racks 108b. In this way, power can be shared between reactors located at different datacenters. Additionally, the sets themselves may be configured in a ring topology across the different datacenters for power sharing and redundancy.

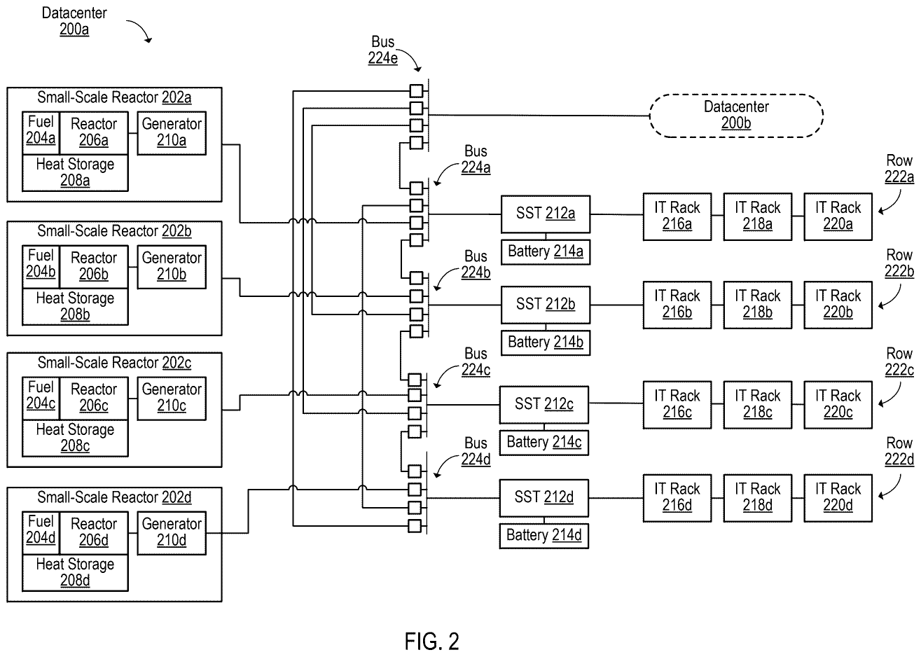

For further explanation, FIG. 2 illustrates a block diagram of an example datacenter that includes a distributed small-scale reactor power system in accordance with some embodiments, depicted in greater detail. The datacenter 200a of FIG. 2 includes small-scale reactors 202a, 202b, 202c, 202d. Each small-scale reactor includes a nuclear reactor 206a, 206b, 206c, 206d, nuclear fuel 204a, 204b, 204c, 204d, heat storage 208a, 208b, 208c, 208d, and a generator 210a, 210b, 210c, 210d. Nuclear reactors 206a-206d utilize nuclear fuel 204a-204d, such as uranium fuel rods or pellets for example, to perform fission which, at a high level, generates heat and steam from a water source. The steam causes a turbine in a generator to spin and produce electricity. In most nuclear reactors, excess heat is generated and must be stored or released. As described below in greater detail, such heat may be utilized in an opportunistic manner in the data center or in other ways.

Each of the small-scale reactors 202a-202d is operatively coupled to an SST 212a, 212b 212c, 212d to provide AC power to the SST. Additionally, the small-scale reactors 202 a-202d are configured in a ring topology, through a set of buses 224a, 224b, 224c, 224d, 224e for power sharing and redundancy. Small-scale reactor 202a, for example, is coupled to bus 224a. Bus 224a is coupled to bus 224d, which is coupled to small-scale reactor 202d. Bus 224d is also coupled to bus 224c, which is coupled to small-scale reactor 202c. Bus 224c is also couped to bus 224b which is coupled to small-scale reactor 202b. Bus 224b is coupled to bus 224a. Continuing the ring, bus 224a is also coupled to bus 224e, which receives power from at least one small-scale reactor at another datacenter 200b. Bus 224e is also coupled to bus 224b, 224c, and 224d. Said another way, each SST is coupled to all small-scale reactors 202a of the datacenter 200a and at least one small-scale reactor in datacenter 200b. In this way, and depending on the capacity of each reactor, an outage of any one of the small-scale reactors 202a-202d does not result in a lack of power capacity for any of the IT racks of the datacenter 200a.

Each SST 212a-212d is coupled to a battery 214a, 214b, 214c, 214d. A battery may be utilized to protect against transient fluctuations in output power of the SST. Examples of battery technologies which may be useful in systems such as the one depicted in FIG. 2 include Lithium-Ion energy storage, super capacitors, and the like.

In the example of FIG. 2, each SST 212a-212d receives AC power from the small-scale reactors 202a-202d (and at least one small-scale reactor from datacenter 200b) and converts the AC power into DC power. Each SST provides power to one or more IT racks organized into a row. SST 212a provides DC power to a row 222a of IT Racks 216a, 218a, 220a. SST 212b provides DC power to a row 222b of IT Racks 216b, 218b, 220b. SST 212c provides DC power to a row 222c of IT Racks 216c, 218c, 220c. SST 212d provides DC power to a row 222d of IT Racks 216d, 218d, 220d. The number of IT racks receiving power from a single power converter is utilized here as an example only. Readers will recognize that due to variations in power demand from different racks or different rows, the number of IT racks receiving power from an SST may vary.

Consider, as an example, that the IT racks of the datacenter 200a require a total power capacity of 20 MWe (‘Megawatts electric’). In such an example, each of the small-scale reactors 202a, 202b, 202c, 202d as well as a small-scale reactor of datacenter 200b may be configured to provide a capacity of 5 MWe. With the configuration shown in FIG. 2, loss of power (whether through a scheduled outage or a malfunction) of any one small-scale reactor, will not result in a power capacity less than the required capacity of 20 MWe for the datacenter 200a. Although the system of FIG. 2 is configured for redundancy to withstand a single small-scale reactor going offline, other configurations may also exist. Consider, for example, the same datacenter 200a with the same 20 MWe capacity requirement. To withstand loss of power from two small-scale reactors, an additional small-scale reactor with a 5 MWe capacity may be added to the set at the datacenter 200a and coupled as part of the ring topology. That is, rather than having four local small-scale reactors and one at another datacenter, the system may include five local small-scale reactors and one at another datacenter. In this way, the amount of redundancy can be designed based on high availability needs of the datacenter. For datacenters requiring an extremely high availability, additional small-scale reactors may be implemented at the datacenter to increase the redundancy and power sharing capabilities of the power system as a whole.

The small-scale reactors 202a-202d of FIG. 2 may be physically located near or within the datacenter. In some embodiments, one or more of the small-scale reactors is constructed and housed in one or more buildings at the same site as the datacenter, but not within the datacenter building itself. Given the modular nature and size of the small-scale reactors, placing the reactors near the datacenter reduces capital investment by reducing the cost of devices and connections between the reactors and the endpoint power consumer.

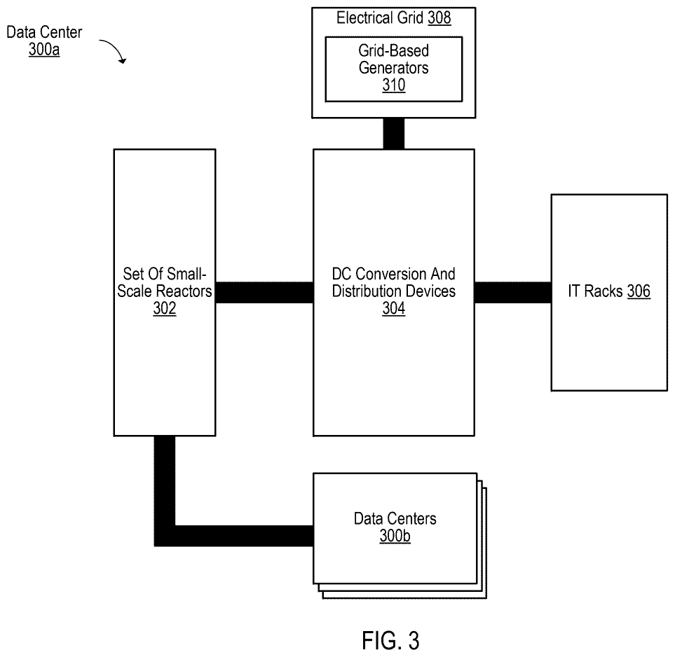

The system of FIG. 2 generally sets forth an example of a self-contained power system in which no utility provided power is utilized by a datacenter. FIG. 3 illustrates a block diagram of an example datacenter that includes a distributed small-scale reactor power system that is coupled to an electrical grid in accordance with some embodiments. FIG. 3 includes a datacenter 300a. The datacenter 300a includes a set 302 of small-scale reactors operatively coupled to provide power to DC conversion and distribution devices 304 (such as the buses 224a-224d and SSTs 212a-212d of FIG. 2). The DC conversion and distribution devices 304 convert the power received from the set 302 of small-scale reactors to DC power and provide the DC power to one or more IT racks 306. Additionally, at least one small-scale reactor from another datacenter 300b is coupled to the set 302 of local reactors to provide AC power to the DC conversion and distribution devices 304.

The datacenter 300a power system is also coupled to an electrical grid 308 and grid-based generators 310. The grid-based generators 310 may be utilized by the set 302 of small-scale reactors for grid-following. In some embodiments, the grid-based generators 310 may provide a frequency and voltage reference to which any of the small-scale reactors may synchronize upon a startup (such as after an outage or at an initial startup). Such grid following also enables the electrical grid the ability to provide power in a redundant manner to the datacenter in case of an outage (scheduled or otherwise) of a small-scale reactor, with reduced fluctuations and transients being introduced. Being in sync, the power from the electrical grid can seamlessly be utilized in case of an outage of a small-scale reactor. Similarly, by synchronizing the voltage and frequency to the grid, the small-scale reactors at the datacenter 300a and other datacenters 300b (assuming those also synchronize to the grid) will be in sync.

When the small-scale reactors and the grid are in sync, the small-scale generators may provide any excess power that is generated (power not utilized by the IT racks of the datacenter) back to the grid. In this way, the small-scale generators may be configured in a highly efficient manner: generating closely the required load plus some additional capacity for redundancy and providing excess power generated to the grid.

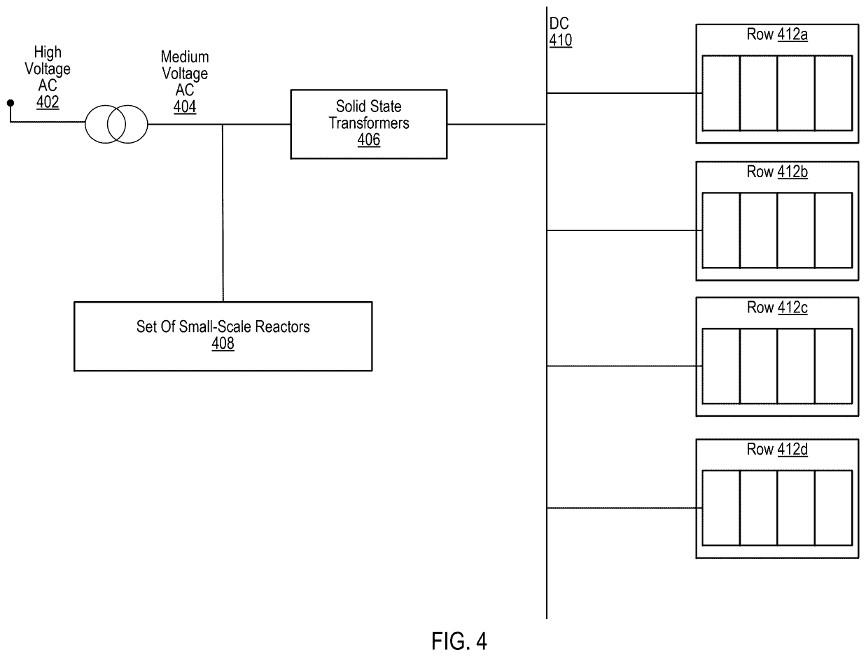

The example in the previous figures generally describe embodiments in which a set of small-scale reactors provides AC power to one or more power converters which converts the AC power to DC power and distributes that DC power to IT racks. While DC power is required by components of the IT racks eventually, the point at which the small-scale reactors are coupled to the power lines of a datacenter's power system may vary. To that end, FIG. 4 sets forth a line diagram of an example power system in accordance with some embodiments in which a set of small-scale reactors is coupled to a Medium voltage AC power supply.

AC power supply is often described as High, Medium, or Low voltage AC. High voltage AC may be in the range of 35 kV to 230 kV, Medium voltage AC may be in the range of 600V to 35 kV, and Low voltage AC may be up to 600V. Transmission lines of the electrical grid normally carry High voltage AC, which is stepped down to Medium voltage AC at one or more substations. Transformers at a datacenter conventionally receive such Medium voltage AC and step down to Low voltage AC for use within the datacenter.

In the example of FIG. 4, High voltage AC 402 is stepped down to Medium voltage AC 404. The set of small-scale reactors 408 in the example of FIG. 4 ties into the power system at the Medium voltage AC 404. A set of SSTs 406 (or other converters) converts the Medium voltage AC to DC voltage 410, which is provided to IT racks of a number of rows 412a, 412b, 412c, 412d.

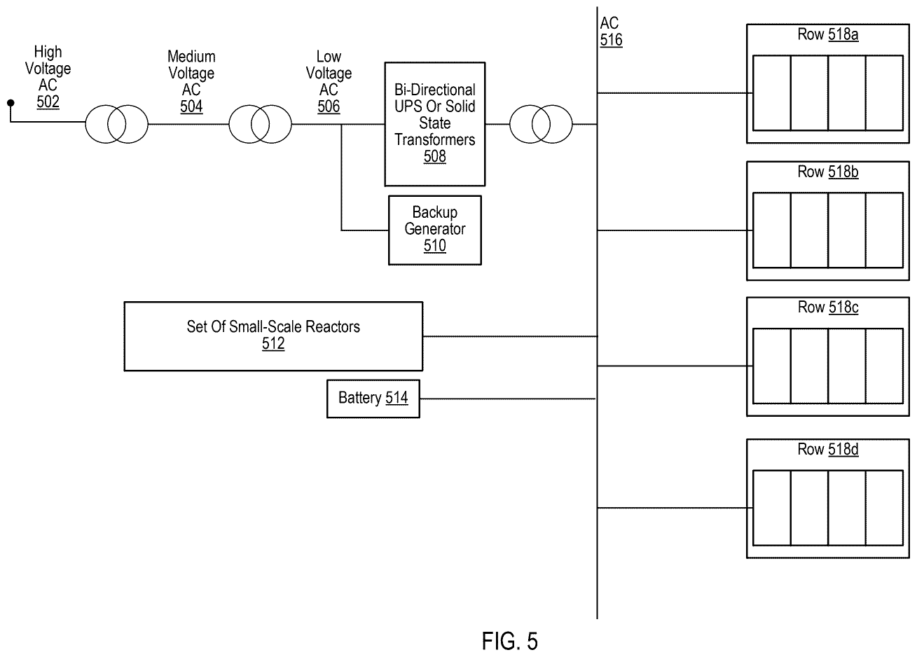

FIG. 5 sets forth a line diagram of another example power system in accordance with some embodiments. In the system of FIG. 5, High voltage AC 502 is stepped down to Medium voltage AC 504 which is then stepped down to Low voltage AC 506. The Low voltage AC 506 is received by SSTs 508, a UPS, or the like, converted to AC power 516 and provided to IT racks in a number of rows 518a, 518b, 518c, 518d. Additionally, a backup generator 510 may be provided at the low voltage AC 506 to provide a secondary redundant low voltage AC supply. Any one or more of the rows 518a-518d, may include power conversion devices, such PSUs, to convert the AC power 516 to DC power and distribute the power throughout the IT racks of rows 518a-518d.

Rather than tying in at the Medium voltage AC, the set 512 of small-scale reactors in the example of FIG. 5 ties into the AC power 516 provided distributed to the rows 518a-518d. In some embodiments, a battery 514 (or any energy storage device) is also coupled to the AC power 516. Such a battery 514 can be utilized to support the AC bus and guard against transient fluctuations introduced by the set 512 of small-scale reactors.

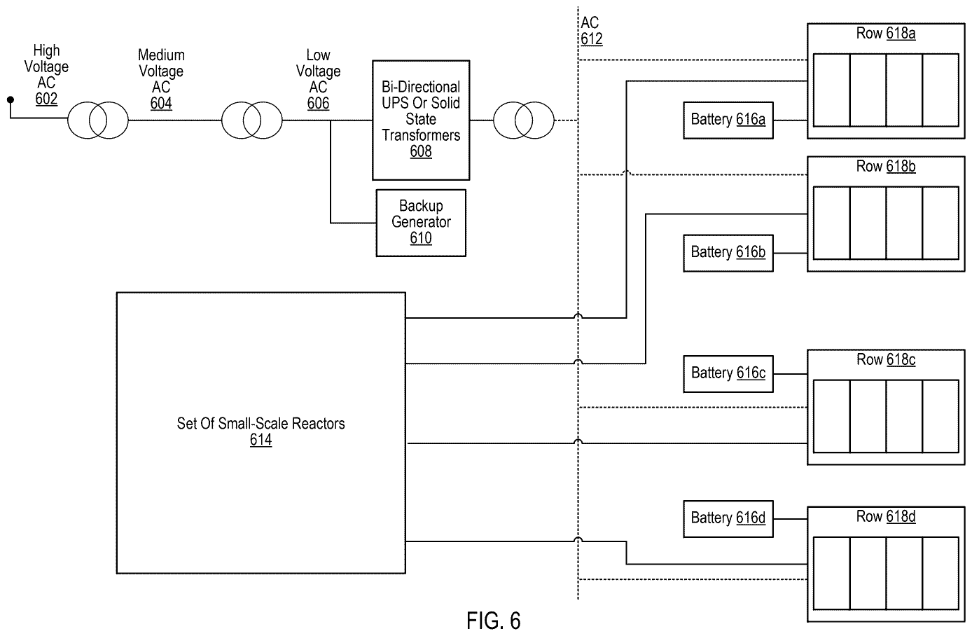

FIG. 6 sets forth a line diagram of yet another example power system in accordance with some embodiments. In the system of FIG. 6, High voltage AC 602 is stepped down to Medium voltage AC 604 which is then stepped down to Low voltage AC 606. The Low voltage AC 606 is received by SSTs 608, a UPS, or the like, which provide converted AC power 612 to IT racks in a number of rows 618a, 618b, 618c, 618d as redundant power. Similar to FIG. 5, a backup generator 610 may be provided at the Low voltage AC 606 to provide an additional redundant Low voltage AC supply. Any one or more of the rows 618a-618d, may include power conversion devices, such PSUs, to convert the AC power 612 to DC power and distribute the power throughout the IT racks of rows 618a-618d.

In the example of FIG. 6, the set 614 of small-scale reactors is coupled to each row to provide AC power which is converted by a converter at each row 618a-616d into DC (in some examples High voltage DC) for use by components of the IT racks of the rows. In some examples, there may be one reactor for each row or one reactor for each IT rack.

Also, in some embodiments, a battery 616a, 616b, 616c, 616d (or supercapacitor or other energy storage device) may be coupled to the power system at each row or at each IT rack. The battery 616a-616d may be utilized as backup power and/or to reduce fluctuations and transient power signals.

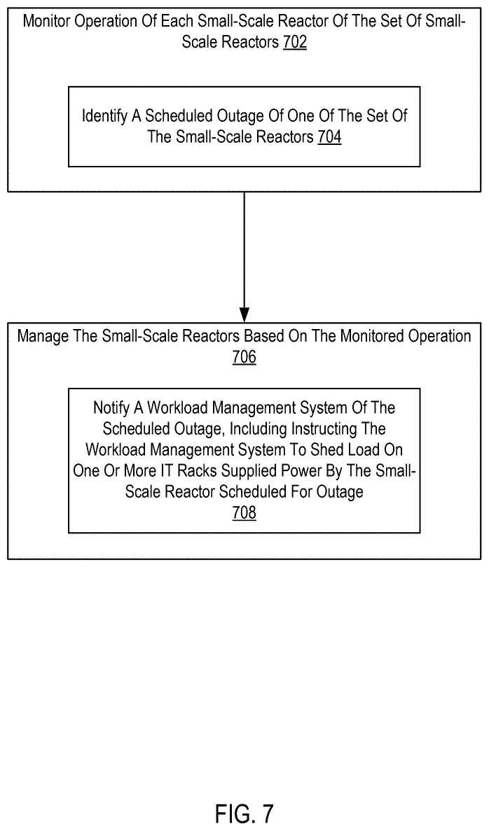

For further explanation, FIG. 7 sets forth a flow chart illustrating an example method for

managing availability of a distributed small-scale reactor power system in accordance with some embodiments. The method of FIG. 7 may be carried out by a computing system, such as server or the like. The computing system may generally be configured to control various operating parameters of a distributed small-scale reactor power system for a datacenter such as those systems described above. For example, the computing system may be configured to control systems to bring a reactor online, bring a reactor offline, monitor operating characteristics of a small-scale reactor such as power output, heat generation, fuel consumption, and the like.

The method of FIG. 5 includes monitoring 702 operation of each small-scale reactor of the set of small-scale reactors and managing 706 the small-scale reactors based on the monitored operation. More specifically, in the method of FIG. 5, monitoring 702 operation of each small-scale reactor may include identifying 704 a scheduled outage of one of the set of the small-scale reactors. The computing system carrying out the steps of the method of FIG. 7 may have access to a schedule of planned outages (for maintenance or the like) or may receive an indication from another system of a such a planned outage.

In the method of FIG. 7, managing the small-scale reactors based on the scheduled outage, includes notifying 708 a workload management system of the scheduled outage. A workload management system as the term is used here is a computing system that executes IT workload management services capable of controlling where workload is executed in a datacenter. To that end, the computing system may instruct the workload management system to shed load on one or more IT racks supplied power by the small-scale reactor scheduled for outage. Consider an example in which one of the small-scale reactors is scheduled for an outage and that small-scale reactor provides primary power to a row of IT racks. In such an example, the workload management system may move IT workloads from the IT racks in that row to other rows or may otherwise reduce the workloads executes in those IT racks. Consider also that some IT workloads have lower availability requirements than others. Such IT workloads may be paused or significantly throttled to reduce the overall power demand of the IT racks of the datacenter.

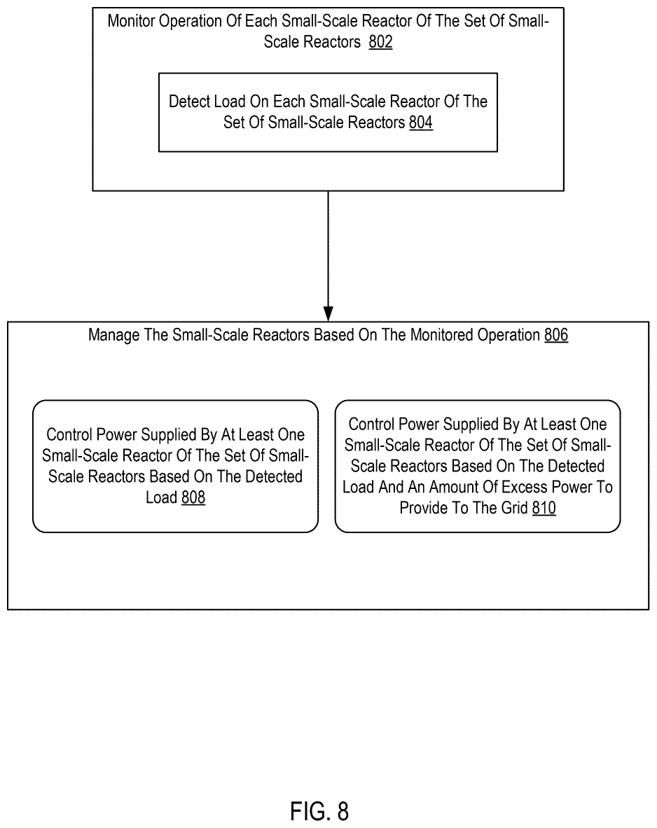

FIG. 8 sets forth a flow chart illustrating another example method for managing availability of a distributed small-scale reactor power system in which load is used to determine power output in accordance with some embodiments. The method of FIG. 8 is similar to the method of FIG. 7 and includes monitoring 802 operation of each small-scale reactor of the set of small-scale reactors and managing 806 the small-scale reactors based on the monitored operation.

In the example of FIG. 8, monitoring 802 the operation of each small-scale reactor includes detecting 804 load on each of the reactors. The load being drawn by the datacenter IT racks on each small-scale reactor may be continuously monitored. In some instances, the load may be less than the overall capacity being generated by the set of small-scale reactors. In such an embodiment, energy being produced is wasted if not otherwise utilized.

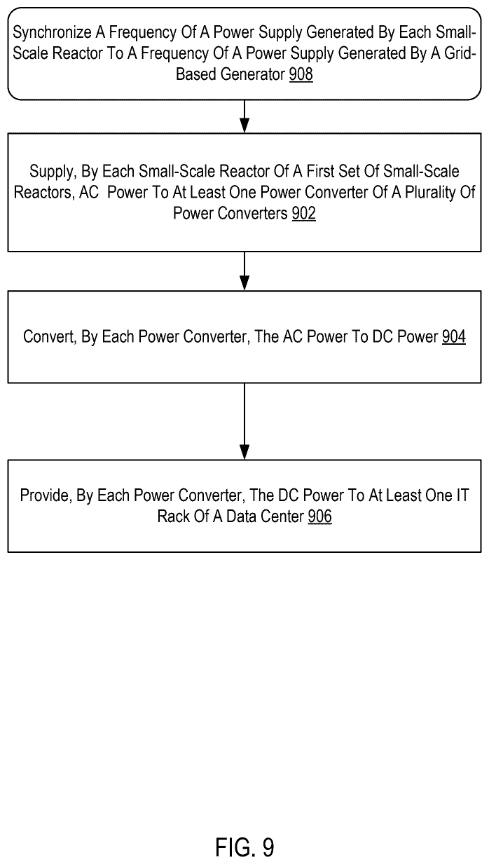

To that end, managing 806 the small-scale reactors in the example of FIG. 8 may include controlling 808 power supplied by at least one of the small-scale reactors based on the load. Controlling 808 the power may include reducing the power generated by one or more of the small-scale reactors to more closely match the load seen at the output. In another example, the method of FIG. 9 may control 810 the power supplied by at least on small-scale reactor based both on the load and an amount of excess power that can be provided to an electrical grid. As explained above, in some embodiments, the set of small-scale reactors may be configured to provide to an electrical grid. In some aspects, providing excess power may be a more efficient use of power generation than merely reducing power generation or wasting excess power generated.

FIG. 9 sets forth a flow chart illustrating a method of providing power by a distributed small-scale reactor power system in accordance with some embodiments. The method of FIG. 9 includes supplying 902, by each small-scale reactor of a first set of small-scale reactors, AC power to at least one power converter of a plurality of power converters. Examples of such power converters may include an SST or a transformer and rectifier system. The method also includes converting 904, by each power converter, the AC power to DC power and providing 906, by each power converter, the DC power to at least one IT rack of a datacenter.

In some embodiments, as described above, the set of small-scale reactors may be configured for grid-following and may be coupled to an electrical grid and/or grid-based generators. To that end, the method of FIG. 9 also includes synchronizing 908 a frequency of a power supply generated by the small-scale reactor to a frequency of a power supply generated by the grid-based generator.

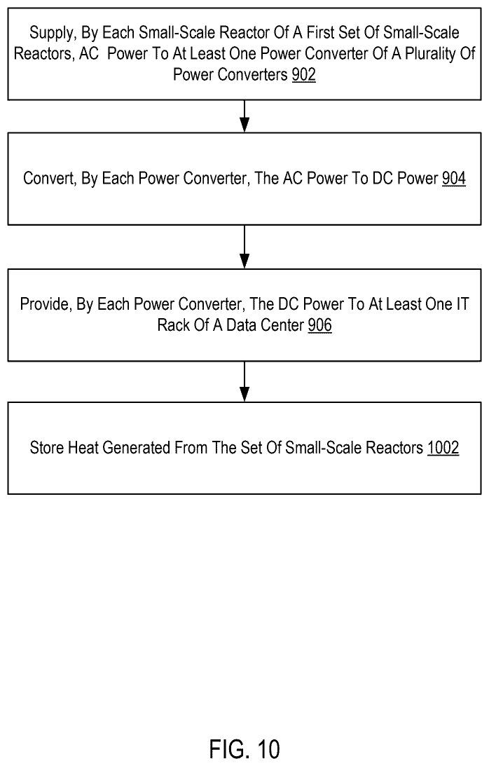

For further explanation FIG. 10 sets forth a flow chart illustrating another method of providing power by a distributed small-scale reactor power system in accordance with some embodiments. The method of FIG. 10 is similar to that of FIG. 9 and includes supplying 902, by a set of small-scale reactors, AC power to at least one power converter, converting 904 the AC power to DC power, and providing 906 the DC power to at least one IT rack of a datacenter.

The method of FIG. 10 differs from that of FIG. 9 in that the method of FIG. 10 also includes storing 1002 heat generated from the set of small-scale reactors. Storing 1002 heat generated from a small-scale reactor may be carried out in a variety of manners. In one example, liquid metals may be utilized to store excess heat generated by a reactor.

Some liquid metals can store heat in a range from 100 degrees Celsius to 700 degrees Celsius. Examples of liquid metals include lead, lead-bismuth alloys such as Lead-bisumuth eutectic alloy, Sodium, Tin, Sodium-Potassium alloys, and the like.

Once stored, the excess heat can be utilized in a variety of manners. In some examples, the excess heat can be utilized for carbon capture or district heating. Carbon capture is a process of capturing carbon dioxide to reduce carbon dioxide emissions. District heating refers to a system for distributing heat generated in a centralized location (in this example, excess heat generated by the small-scale reactors) through a system of insulated pipes for heating purposes throughout a building or facility.

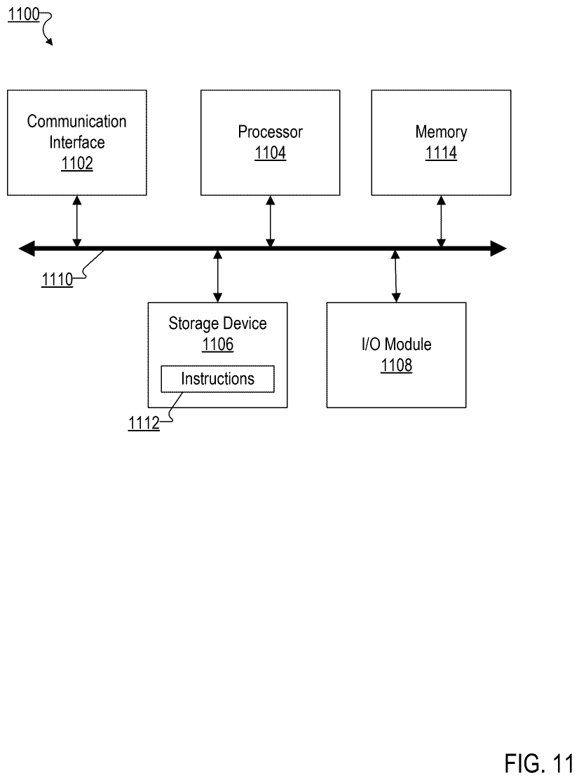

For further explanation, FIG. 11 illustrates an exemplary computing device 1100 that may be specifically configured to perform one or more of the processes described herein. More specifically, the example computing device 1100 in FIG. 11 may operate to manage availability of a distributed small-scale reactor system in accordance with the example methods set forth in FIGS. 7 and 8. As shown in FIG. 11, computing device 1100 may include a communication interface 1102, a processor 1104, a storage device 1106, an input/output (I/O) module 1108, and computer memory 1114 communicatively connected one to another via a communication infrastructure 1110. While an exemplary computing device 1100 is shown in FIG. 11, the components illustrated in FIG. 11 are not intended to be limiting. Additional or alternative components may be used in other embodiments. Components of computing device 1100 shown in FIG. 11 will now be described in additional detail.

Communication interface 1102 may be configured to communicate with one or more computing devices. Examples of communication interface 1102 include, without limitation, a wired network interface (such as a network interface card), a wireless network interface (such as a wireless network interface card), a modem, an audio/video connection, and any other suitable interface.

Processor 1104 generally represents any type or form of processing unit capable of processing data and/or interpreting, executing, and/or directing execution of one or more of the instructions, processes, and/or operations described herein. Processor 1104 may perform operations by executing computer-executable instructions 1112 (e.g., an application, software, code, and/or other executable data instance) stored in storage device 1106.

Storage device 1106 may include one or more data storage media, devices, or configurations and may employ any type, form, and combination of data storage media and/or device. For example, storage device 1106 may include, but is not limited to, any combination of non-volatile media and/or volatile media. Electronic data, including data described herein, may be temporarily and/or permanently stored in storage device 1106. For example, data representative of computer-executable instructions 1112 configured to direct processor 1104 to perform any of the operations described herein may be stored within storage device 1106. In some examples, data may be arranged in one or more databases residing within storage device 1106.

I/O module 1108 may include one or more I/O modules configured to receive user input and provide user output. I/O module 1108 may include any hardware, firmware, software, or combination thereof supportive of input and output capabilities. For example, I/O module 1108 may include hardware and/or software for capturing user input, including, but not limited to, a keyboard or keypad, a touchscreen component (e.g., touchscreen display), a receiver (e.g., an RF or infrared receiver), motion sensors, and/or one or more input buttons.

I/O module 1108 may include one or more devices for presenting output to a user, including, but not limited to, a graphics engine, a display (e.g., a display screen), one or more output drivers (e.g., display drivers), one or more audio speakers, and one or more audio drivers. In certain embodiments, I/O module 1108 is configured to provide graphical data to a display for presentation to a user. The graphical data may be representative of one or more graphical user interfaces and/or any other graphical content as may serve a particular implementation. In some examples, any of the systems, computing devices, and/or other components described herein may be implemented by computing device 1100.

Advantages and features of the present disclosure can be further described by the following clauses:

Clause 1. A distributed small-scale reactor power system comprising: a first set of small-scale reactors configured to supply power to a datacenter comprising a plurality of IT (‘Information Technology’) racks; and a set of power converters, wherein each small-scale reactor is operatively coupled to at least one power converter, and each power converter is operatively coupled to at least one IT rack.

Clause 2. The system of clause 1, wherein: the small-scale reactors are configured in a ring topology to provide redundant AC (‘Alternating Current’) power to the power converters; and each of the power converters is configured to receive AC power from two or more of the small-scale reactors and provide DC (‘Direct Current’) power.

Clause 3. The system of clause 1 or 2, wherein the first set of small-scale reactors comprises one of a plurality of sets of small-scale reactors and the plurality of sets of small-scale reactors is configured in a ring topology to provide redundant power to a plurality of datacenters.

Clause 4. The system of clause 1, 2, or 3, wherein: each of the first set of small-scale reactors is coupled to a grid-based generator and is configured to synchronize a frequency of a power supply generated by the small-scale reactor to a frequency of a power supply generated by the grid-based generator.

Clause 5. The system of clause 1, 2, 3, or 4, wherein each of the first set of small-scale reactors is configured for grid forming, including providing voltage and frequency to a microgrid of the datacenter.

Clause 6. The system of clause 1, 2, 3, 4, or 5, wherein at least one of the power converters comprises a solid-state transformer or any conversion device that provides power to IT racks.

Clause 7. The system of clause 6, wherein each solid-state transformer is coupled to a power storage device configured to mitigate transient output power.

Clause 8. The system of clause 1, 2, 3, 4, 5, or 6, further comprising: heat storage configured to capture and store heat generated from the set of small-scale reactors.

Clause 9. An apparatus for managing availability in a datacenter, wherein the datacenter comprises a plurality of IT (‘Information Technology’) racks, each IT rack is provided power by a power converter, and each power converter receives power from at least one of a set of small-scale reactors, wherein the apparatus comprises: a processing device; and a memory device operatively coupled to the processing device, where the processing device is configured to: monitor operation of each small-scale reactor of the set of small-scale reactors; and manage the small-scale reactors based on the monitored operation.

Clause 10. The apparatus of clause 9, wherein the processing device is further configured to: identify a scheduled outage of one of the set of the small-scale reactors; and notify a workload management system of the scheduled outage, including instructing the workload management system to shed load on one or more IT racks supplied power by the small-scale reactor scheduled for outage.

Clause 11. The apparatus of clause 9 or 10, wherein the processing device is further configured to: detect load on each small-scale reactor of the set of small-scale reactors; and control power supplied by at least one small-scale reactor of the set of small-scale reactors based on the detected load.

Clause 12. The apparatus of clause 9, 10, or 11, wherein the set of small-scale reactors is coupled to an electrical grid and configured to provide excess power to the electrical grid, and the processing device is further configured to: detect load on each small-scale reactor of the set of small-scale reactors; and control power supplied by at least one small-scale reactor of the set of small-scale reactors based on the detected load and an amount of excess power to provide to the grid.

Clause 13. The apparatus of clause 9, 10, 11, or 12, wherein: the small-scale reactors are configured in a ring topology to provide redundant AC (‘Alternating Current’) power to the power converters; and each of the power converters is configured to receive AC power from two or more of the small-scale reactors and provide DC (‘Direct Current’) power or AC power.

Clause 14. The apparatus of clause 13, wherein the set of small-scale reactors comprises one of a plurality of sets of small-scale reactors and the plurality of sets of small-scale reactors is configured in a ring topology to provide redundant power to a plurality of datacenters.

Clause 15. A method comprising: supplying, by each small-scale reactor of a first set of small-scale reactors, AC (‘Alternative Current’) power to at least one power converter of a plurality of power converters; converting, by each power converter, the AC power to DC (‘Direct Current’) power; and providing, by each power converter, the DC power to at least one IT rack of a datacenter.

Clause 16. The method of clause 15, wherein: the small-scale reactors are configured in a ring topology to provide redundant AC power to the power converters; and each of the power converters is configured to receive AC power from two or more of the small-scale reactors and provide DC (‘Direct Current’) power.

Clause 17. The method of clause 15 or 16, wherein the first set of small-scale reactors comprises one of a plurality of sets of small-scale reactors and the plurality of sets of small-scale reactors is configured in a ring topology to provide redundant power to a plurality of datacenters.

Clause 18. The method of clause 15, 16, or 17, wherein: each of the first set of small-scale reactors is coupled to a grid-based generator and is configured to synchronize a frequency of a power supply generated by the small-scale reactor to a frequency of a power supply generated by the grid-based generator.

Clause 19. The method of clause 15, 16, 17, or 18, wherein each of the first set of small-scale reactors is configured for grid forming, including providing voltage and frequency support to a microgrid of the datacenter.

Clause 20. The method of clause 15, 16, 17, 18, or 19, further comprising: storing heat generated from the set of small-scale reactors.

Although some embodiments are described largely in the context of a system, method, or in some other way, readers will recognize that embodiments of the present disclosure may also take the form of a computer program product disposed upon computer readable storage media for use with any suitable processing system. Such computer readable storage media may be any storage medium for machine-readable information, including magnetic media, optical media, solid-state media, or other suitable media. Examples of such media include magnetic disks in hard drives or diskettes, compact disks for optical drives, magnetic tape, and others as will occur to those of skill in the art. Persons skilled in the art will immediately recognize that any computer system having suitable programming means will be capable of executing the steps described herein as embodied in a computer program product. Persons skilled in the art will recognize also that, although some of the embodiments described in this specification are oriented to software installed and executing on computer hardware, nevertheless, alternative embodiments implemented as firmware or as hardware are well within the scope of the present disclosure.

Readers will appreciate that some embodiments are described in which computer program instructions are executed on computer hardware such as, for example, one or more computer processors. Readers will appreciate that in other embodiments, computer program instructions may be executed on virtualized computer hardware (e.g., one or more virtual machines), in one or more containers, in one or more cloud computing instances (e.g., one or more AWS EC2 instances), in one or more serverless compute instances offered such as those offered by a cloud services provider, in one or more event-driven compute services such as those offered by a cloud services provider, or in some other execution environment.

In some examples, a non-transitory computer-readable medium storing computer-readable instructions may be provided in accordance with the principles described herein. The instructions, when executed by a processor of a computing device, may direct the processor and/or computing device to perform one or more operations, including one or more of the operations described herein. Such instructions may be stored and/or transmitted using any of a variety of known computer-readable media.

A non-transitory computer-readable medium as referred to herein may include any non-transitory storage medium that participates in providing data (e.g., instructions) that may be read and/or executed by a computing device (e.g., by a processor of a computing device). For example, a non-transitory computer-readable medium may include, but is not limited to, any combination of non-volatile storage media and/or volatile storage media. Exemplary non-volatile storage media include, but are not limited to, read-only memory, flash memory, a solid-state drive, a magnetic storage device (e.g., a hard disk, a floppy disk, magnetic tape, etc.), ferroelectric random-access memory (“RAM”), and an optical disc (e.g., a compact disc, a digital video disc, a Blu-ray disc, etc.). Exemplary volatile storage media include, but are not limited to, RAM (e.g., dynamic RAM).

One or more embodiments may be described herein with the aid of method steps illustrating the performance of specified functions and relationships thereof. The boundaries and sequence of these functional building blocks and method steps have been arbitrarily defined herein for convenience of description. Alternate boundaries and sequences can be defined so long as the specified functions and relationships are appropriately performed. Any such alternate boundaries or sequences are thus within the scope and spirit of the claims. Further, the boundaries of these functional building blocks have been arbitrarily defined for convenience of description. Alternate boundaries could be defined as long as the certain significant functions are appropriately performed. Similarly, flow diagram blocks may also have been arbitrarily defined herein to illustrate certain significant functionality.

To the extent used, the flow diagram block boundaries and sequence could have been defined otherwise and still perform the certain significant functionality. Such alternate definitions of both functional building blocks and flow diagram blocks and sequences are thus within the scope and spirit of the claims. One of average skill in the art will also recognize that the functional building blocks, and other illustrative blocks, modules and components herein, can be implemented as illustrated or by discrete components, application specific integrated circuits, processors executing appropriate software and the like or any combination thereof.

While particular combinations of various functions and features of the one or more embodiments are expressly described herein, other combinations of these features and functions are likewise possible. The present disclosure is not limited by the particular examples disclosed herein and expressly incorporates these other combinations.

What is claimed is:

1. A distributed small-scale reactor power system comprising:
a first set of small-scale reactors configured to supply power to a datacenter comprising a plurality of IT (‘Information Technology’) racks; and
a set of power converters, wherein each small-scale reactor is operatively coupled to at least one power converter, and each power converter is operatively coupled to at least one IT rack.

2. The system of claim 1, wherein:
the small-scale reactors are configured in a ring topology to provide redundant AC (‘Alternating Current’) power to the power converters; and
each of the power converters is configured to receive AC power from two or more of the small-scale reactors and provide DC (‘Direct Current’) power.

3. The system of claim 1, wherein the first set of small-scale reactors comprises one of a plurality of sets of small-scale reactors and the plurality of sets of small-scale reactors is configured in a ring topology to provide redundant power to a plurality of datacenters.

4. The system of claim 1, wherein:
each of the first set of small-scale reactors is coupled to a grid-based generator and is configured to synchronize a frequency of a power supply generated by the small-scale reactor to a frequency of a power supply generated by the grid-based generator.

5. The system of claim 1, wherein each of the first set of small-scale reactors is configured for grid forming, including providing voltage and frequency support to a microgrid of the datacenter.

6. The system of claim 1, wherein at least one of the power converters comprises a solid-state transformer.

7. The system of claim 6, wherein each solid-state transformer is coupled to a power storage device configured to mitigate transient output power.

8. The system of claim 1, further comprising:
heat storage configured to capture and store heat generated from the set of small-scale reactors.

9. An apparatus for managing availability in a datacenter, wherein the datacenter comprises a plurality of IT (‘Information Technology’) racks, each IT rack is provided power by a power converter, and each power converter receives power from at least one of a set of small-scale reactors, wherein the apparatus comprises:
a processing device; and
a memory device operatively coupled to the processing device, where the processing device is configured to:
monitor operation of each small-scale reactor of the set of small-scale reactors; and
manage the small-scale reactors based on the monitored operation.

10. The apparatus of claim 9, wherein the processing device is further configured to:
identify a scheduled outage of one of the set of the small-scale reactors; and
notify a workload management system of the scheduled outage, including instructing the workload management system to shed load on one or more IT racks supplied power by the small-scale reactor scheduled for outage.

11. The apparatus of claim 9, wherein the processing device is further configured to:
detect load on each small-scale reactor of the set of small-scale reactors; and
control power supplied by at least one small-scale reactor of the set of small-scale reactors based on the detected load.

12. The apparatus of claim 9, wherein the set of small-scale reactors is coupled to an electrical grid and configured to provide excess power to the electrical grid, and the processing device is further configured to:
detect load on each small-scale reactor of the set of small-scale reactors; and
control power supplied by at least one small-scale reactor of the set of small-scale reactors based on the detected load and an amount of excess power to provide to the grid.

13. The apparatus of claim 9, wherein:
the small-scale reactors are configured in a ring topology to provide redundant AC (‘Alternating Current’) power to the power converters; and
each of the power converters is configured to receive AC power from two or more of the small-scale reactors and provide DC (‘Direct Current’) power.

14. The apparatus of claim 13, wherein the set of small-scale reactors comprises one of a plurality of sets of small-scale reactors and the plurality of sets of small-scale reactors is configured in a ring topology to provide redundant power to a plurality of datacenters.

15. A method comprising:
supplying, by each small-scale reactor of a first set of small-scale reactors, AC (‘Alternative Current’) power to at least one power converter of a plurality of power converters;
converting, by each power converter, the AC power to DC (‘Direct Current’) power; and
providing, by each power converter, the DC power to at least one IT rack of a datacenter.

16. The method of claim 15, wherein:
the small-scale reactors are configured in a ring topology to provide redundant AC power to the power converters; and
each of the power converters is configured to receive AC power from two or more of the small-scale reactors and provide DC (‘Direct Current’) power.

17. The method of claim 15, wherein the first set of small-scale reactors comprises one of a plurality of sets of small-scale reactors and the plurality of sets of small-scale reactors is configured in a ring topology to provide redundant power to a plurality of datacenters.

18. The method of claim 15, wherein:
each of the first set of small-scale reactors is coupled to a grid-based generator and is configured to synchronize a frequency of a power supply generated by the small-scale reactor to a frequency of a power supply generated by the grid-based generator.

19. The method of claim 15, wherein each of the first set of small-scale reactors is configured for grid forming, including providing voltage and frequency support to a microgrid of the datacenter.

20. The method of claim 15, further comprising:
storing heat generated from the set of small-scale reactors.
